(19) United States
(12) Patent Application Publication
(10) Pub. No.: US 2016/0231389 A1
(43) Pub. Date: Aug. 11, 2016

(54) DETERIORATION FUNCTION CALCULATION DEVICE, DETERIORATION RATE ESTIMATION DEVICE, DETERIORATION RATE ESTIMATION SYSTEM, DETERIORATION FUNCTION CALCULATION METHOD, DETERIORATION RATE ESTIMATION METHOD, AND PROGRAM

(71) Applicant: MITSUBISHI HEAVY INDUSTRIES, LTD., Tokyo (JP)

(72) Inventors: Kazuyuki WAKASUGI, Tokyo (JP); Toshihiko NIINOMI, Tokyo (JP); Katsuaki MORITA, Tokyo (JP); Takayuki KONO, Tokyo (JP); Hisashi MOTOYAMA, Tokyo (JP); Masato SUZUKI, Tokyo (JP)

(21) Appl. No.: 15/022,289

(22) PCT Filed: Oct. 16, 2014
(86) PCT No.: PCT/JP2014/077604

§ 371 Date: Mar. 16, 2016

(30) Foreign Application Priority Data
Oct. 22, 2013 (JP) 2013-219352

(51) Int. Cl. G01R 31/36

(52) U.S. Cl. CPC G01R 31/3679; G01R 31/3648

(57) ABSTRACT

The deterioration function calculation device includes: a storage unit which stores the running time of the secondary battery during the use in association with the deterioration rate of the secondary battery during the running time; an equivalent coefficient calculation unit which calculates an equivalent coefficient for normalizing the running time, on the basis of values related to the use; an equivalent running time calculation unit which calculates an equivalent running time on the basis of the running time and the equivalent coefficient related to the use related to the running time; and a deterioration function calculation unit which calculates a deterioration function representing a relationship between the equivalent running time and the deterioration rate.

### TECHNICAL FIELD

The present invention relates to a deterioration function calculation device, a deterioration function calculating method, and a program which calculate a deterioration function related to a deterioration rate of a secondary battery and a deterioration rate estimation device, a deterioration rate estimation system, a deterioration rate estimating method, and a program which estimate deterioration of a secondary battery.

Priority is claimed on Japanese Patent Application No. 2013-219352, filed Oct. 22, 2013, the content of which is incorporated herein by reference.

### BACKGROUND ART

In operating secondary batteries, it is necessary to diagnose deterioration thereof and estimate the remaining life thereof. Deterioration curves indicating relationships of running times and deterioration rates of secondary batteries when the secondary batteries are operated in general aspects are illustrated in catalogues of the secondary batteries in some cases. When such deterioration curves can be referred to, the deterioration curves can be compared with cycle rates in operating current secondary batteries to estimate the life of the secondary batteries. However, since aspects illustrated in catalogues and actual usage aspects generally differ, there are differences between relationships of actual running times to deterioration rates and the deterioration curves illustrated in the catalogues.

A technique of estimating a deterioration state and the remaining life of a secondary battery by providing upper threshold values in operating a current/temperature/state-of-charge (SOC) of the secondary battery and using the number of times relevant values exceed the upper threshold values in the operating as a parameter is disclosed in Patent Literature 1.

### CITATION LIST

### Patent Literature

Patent Literature 1

Japanese Unexamined Patent Application, First Publication No. 2010-139260

### SUMMARY OF INVENTION

### Problems to be Solved by the Invention

The technique disclosed in Patent Literature 1 estimates the life of the secondary battery using a formula of estimating deteriorated states generated based on shapes and items of different formulae. For this reason, the technique disclosed in Patent Literature 1 can generate a deterioration estimating formula based on history information when the secondary battery was operated in the same load pattern in the past and accurately estimate deterioration of the secondary battery operated in the same load pattern when the deterioration is estimated. However, the technique disclosed in Patent Literature 1 may not be capable of accurately estimating deterioration of the secondary battery operated in an unknown load pattern when the deterioration is estimated.

An object of the present invention is to provide a deterioration function calculation device, a deterioration rate estimation device, a deterioration rate estimation system, a deterioration function calculating method, a deterioration rate estimating method, and a program for the purpose of accurately estimating a deterioration rate even when a secondary battery is operated in an unknown operation aspect.

### Means for Solving the Problem

According to a first aspect of the present invention, a deterioration function calculation device includes a storage unit, an equivalent coefficient calculation unit, an equivalent running time calculation unit, and a deterioration function calculation unit. The storage unit associates and stores running times of a secondary battery in previous operations of the secondary battery with deterioration rates of the secondary battery in the running times for each operation. The equivalent coefficient calculation unit calculates equivalent coefficients used for normalizing the running times based on values related to the previous operations in the secondary battery for each operation. The equivalent running time calculation unit calculates equivalent running times that are the normalized running times based on the running times and the equivalent coefficients related to the operations relevant to the running times with respect to the running times associated and stored with the operations and the deterioration rates by the storage The deterioration function calculation unit calculates a deterioration function indicating relationships of the equivalent running times and the deterioration rates based on the equivalent running times and the deterioration rates associated with the running times used for calculating the equivalent running times and stored by the storage unit.

According to a second aspect of the present invention, in the first aspect, the deterioration function calculation device is an equivalent coefficient calculation unit generating the equivalent coefficients such that degrees of scattering between the deterioration rates stored by the storage unit, and the equivalent running times calculated based on the running times associated with the deterioration rates and the deterioration rates acquired from the deterioration function become smaller.

According to a third aspect of the present invention, in the first or second aspect, the deterioration function calculation device is an equivalent running time calculation unit dividing the running times into partial running times for each operation state, multiplying the partial running times by the equivalent coefficients according to operation states, calculating a sum thereof, and calculating the equivalent running times.

According to a fourth aspect of the present invention, a deterioration rate estimation device includes an input unit, an equivalent coefficient calculation unit, an equivalent running time calculation unit, and a deterioration rate estimation unit. The input unit receives inputs of running times of a secondary battery and values related to operations of the secondary battery. The equivalent coefficient calculation unit calculates equivalent coefficients used fur normalizing the running times based on the values related to the operations received as the inputs. The equivalent running time calculation unit calculates equivalent running times that are the normalized running times based on the running times received as the inputs and the equivalent coefficients. The deterioration rate estimation unit estimates the deterioration rates of the secondary battery based on a deterioration function indicating relationships of the equivalent running times and the deterioration rates of the secondary battery, and the calculated equivalent running times.

According to a fifth aspect of the present invention, In the fourth aspect, the deterioration rate estimation device is the deterioration rate estimation unit estimating the deterioration rates of the secondary battery based on a deterioration function calculated by the deterioration function calculation unit of the deterioration function calculation device according to any one of the first and third aspects and the calculated equivalent running times.

According to a sixth aspect of the present invention, a deterioration function calculating method of calculates a deterioration function used for estimating deterioration rates of a secondary battery. The deterioration function calculating method includes a step of calculating, by a deterioration function calculation device, equivalent coefficients used for normalizing running times of the secondary battery based on values related to previous operations of the secondary battery for each operation. The deterioration function calculating method includes a step of calculating, by the deterioration function calculation device, equivalent running times that are the normalized running times bases on the running times and the equivalent coefficients related to the operations relevant to the running times with respect to the running times associated and stored with the operations and the deterioration rates in a storage unit. The storage unit associates and stores the running times of the secondary battery in the previous operations of the secondary battery with the deterioration rates of the secondary battery in the running times for each operation. The deterioration function calculating method includes a step of calculating, by the deterioration function calculation device, a deterioration function indicating relationship between the equivalent running times and the deterioration rates based on the equivalent running times and the deterioration rates associated with the running times used for calculating the equivalent running times and stored by the storage unit.

A seventh aspect of the present invention is a deterioration rate estimating method of a secondary battery. The deterioration rate estimating method includes a step of receiving, by a deterioration rate estimation device, inputs of running times of the secondary battery and values related to operations of the secondary battery. The deterioration rate estimating method includes a step of calculating, by the deterioration rate estimation device, equivalent coefficients used for normalizing the running times based on the values related to the operations received as the inputs. The deterioration rate estimating method includes a step of calculating, by the deterioration rate estimation device, equivalent running times that are the normalized running times based on the running times received as the inputs and the equivalent coefficients. The deterioration rate estimating method includes a step of estimating, by the deterioration rate estimation device, the deterioration rates of the secondary battery based on a deterioration function indicating relationships of the equivalent running times and the deterioration rates of the secondary battery, and the calculated equivalent running times.

An eighth aspect of the present invention is a program causing a computer to function as a storage unit, an equivalent coefficient calculation unit, an equivalent running time calculation unit, and a deterioration function calculation unit. The storage unit associates and stores running times of a secondary battery in previous operations of the secondary battery with deterioration rates of the secondary battery in the running times for each operation. The equivalent coefficient calculation unit calculates equivalent coefficients used for normalizing the running times based on values related to the previous operations in the secondary battery for each operation. The equivalent running time calculation unit calculates equivalent running times that are the normalized running times based on the running times and the equivalent coefficients related to the operations relevant to the running times with respect to the running times associated and stored with the operations and the deterioration rates by the storage unit. The deterioration function calculation unit calculates deterioration function indicating a relationship between the equivalent running times and the deterioration rates based on the equivalent running times and the deterioration rates associated with the running times used for calculating the equivalent running times and stored by the storage unit.

A ninth aspect of the present invention is a program causing a computer to function as an input unit, an equivalent coefficient calculation unit, an equivalent running time calculation unit, and a deterioration rate estimation unit. The input unit receives inputs of the running times of the secondary battery and values related to the operations of the secondary battery The equivalent coefficient calculation unit calculates equivalent coefficients used for normalizing the running times based on the values related to the operations received as the inputs. The equivalent running time calculation unit calculates equiv it running times that are the normalized running times based on the running times received as the inputs and the equivalent coefficients. The deterioration rate estimation unit estimates the deterioration rates of the secondary battery based on a deterioration function indicating relationships of the equivalent running times and the deterioration rates of the secondary battery, and the calculated equivalent running times.

In addition, a tenth aspect is a deterioration rate estimation system including a storage unit, a first equivalent coefficient calculation unit, a first equivalent running time calculation unit, a deterioration function calculation unit, an input unit, a second equivalent coefficient calculation unit, a second equivalent running time calculation unit, and a deterioration rate estimation unit. The storage unit associates and stores running times of a secondary battery in previous operations of the secondary battery with deterioration rates of the secondary battery in the running times for each operation. The first equivalent coefficient calculation unit calculates equivalent coefficients used for normalizing the running times based on values related to the previous operations in the secondary battery for each operation. The first equivalent running time calculation unit calculates equivalent running times that are the nomalized running times based on the running times and the equivalent coefficients calculated by the first equivalent coefficient calculation unit with respect to the running times associated and stored with the operations and the deterioration rates by the storage unit. The deterioration function calculation unit configured to calculate a deterioration function indicating relationships of the equivalent running times and the deterioration rates based on the equivalent running times calculated by the first equivalent running time calculation unit and the deterioration rates associated and stored with the running times used for calculating the equivalent running times by the storage unit. The second equivalent coefficient calculation unit calculates equivalent coefficients used for normalizing the running times based on the values related to the operations received as the inputs. The second equivalent running time calculation unit calculates equivalent running times that are the normalized running times based on the running times received as the inputs and the equivalent coefficients calculated by the second equivalent coefficient calculation unit. The deterioration rate estimation unit estimates the deterioration rates of the secondary battery based on the deterioration function calculated by the deterioration function calculation unit and the equivalent running times calculated by the second equivalent running time calculation unit.

### Effects of the Invention

According to at least one of the above-mentioned aspects, the deterioration function calculation device can calculate the deterioration function for the purpose of accurately estimating the deterioration rate even when the secondary battery is operated in an unknown operation aspect. According to at least one of the above-mentioned aspects, the deterioration rate estimation device can accurately estimate the deterioration rate even when the secondary battery is operated in an unknown operation aspect.

### BRIEF DESCRIPTION OF DRAWINGS

FIG. 1 is a schematic block diagram showing a constitution of a deterioration rate estimation system according to a first embodiment.

FIG. 2 is a flowchart showing a method of calculating a deterioration function according to the first embodiment.

FIG. 3 is a flowchart showing a method of estimating a deterioration rate according to the first embodiment.

FIG. 4A is a view showing an example of the method of calculating the deterioration function according to the first embodiment.

FIG. 4B is a view showing an example of the method of calculating the deterioration function according to the first embodiment.

FIG. 5 is a schematic block diagram showing a constitution of a deterioration rate estimation system according to a second embodiment.

FIG. 6 is a flowchart showing a method of calculating deterioration function according to the second embodiment.

FIG. 7 is a flowchart showing a method of estimating a deterioration rate according to the second embodiment.

FIG. 8 is a schematic block diagram showing a constitution of a computer according to at least one embodiment.

### DESCRIPTION OF EMBODIMENTS

### First Embodiment

Hereinafter, embodiments will be described in detail reference to the drawings.

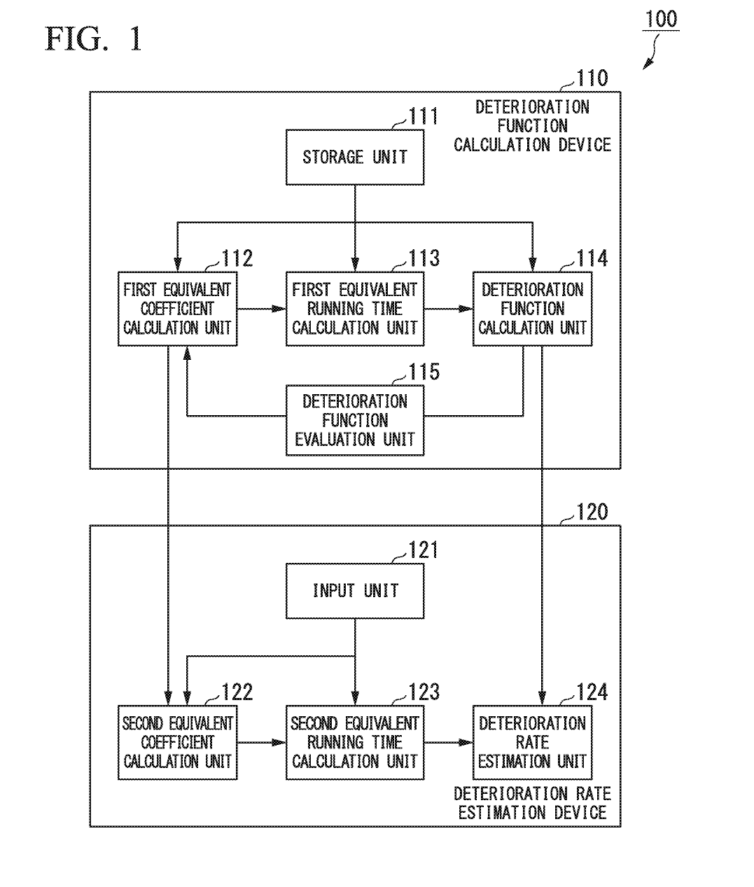

FIG. 1 is a schematic block diagram showing a constitution of a deterioration rate estimation system 100 according to a first embodiment.

The deterioration rate estimation system 100 estimates a deterioration rate of a secondary battery. The deterioration rate estimation system 100 includes a deterioration function calculation device 110 and a deterioration rate estimation device 120.

The deterioration function calculation device 110 calculates a deterioration function used for estimating the deterioration rate of the secondary battery. A deterioration ion curve is an aspect of the deterioration function. The deterioration function can be expressed as a graph to acquire the deterioration curve. The deterioration function calculation device 110 includes a storage unit 111, a first equivalent coefficient calculation unit 112, a first equivalent running time calculation unit 113, a deterioration function calculation unit 114, and a deterioration function evaluation unit 115.

The storage unit 111 associates and stores running times of the secondary battery in previous operations of the secondary battery and values related to the operations of the secondary battery when the running times have passed and deterioration rates of the secondary battery when the running times have passed for each operation. In the embodiment, the storage unit 111 stores a plurality of types of values such as a charging rate, a temperature, a current, and a voltage as the values related to the operations of the secondary battery.

The first equivalent coefficient calculation unit 112 calculates equivalent coefficients used for normalizing the running times based on the values related to the operations of the secondary battery stored by the storage unit 111. To be specific, then equivalent coefficients for certain passage times stored by the storage unit 111 are calculated, the first equivalent coefficient calculation unit 112 acquires a plurality of values related to operations until the running times pass after an operation of the secondary battery from the storage unit 111 starts and specifies a usage range of a charging rate, a change rate of the charging rate, operation patterns of a maximum current value, etc. based on the values. The operation patterns are also examples of the values related to the operations of the secondary battery. The first equivalent coefficient calculation unit 112 substitutes the specified operation patterns into a predetermined equivalent coefficient calculating formula and calculates the equivalent coefficient. Note that the equivalent coefficient calculated by the first equivalent coefficient calculation unit 112 is not limited to one. When an equivalent running time calculating formula used for calculating equivalent running times uses a plurality of equivalent coefficients, the first equivalent coefficient calculation unit 112 calculates a plurality of equivalent coefficients. The equivalent coefficient calculating formula is appropriately updated in a process of calculating the deterioration function. A type of the equivalent coefficient calculating formula and initial values of dependent variables are determined in a previous stage of the process of calculating the deterioration function in advance.

The first equivalent running time calculation unit 113 calculates equivalent running times that are the normalized running times based on the running times and the equivalent coefficients stored by the storage unit 111. To be specific, the first equivalent running time calculation unit 113 specifies the operation associated with the running time and substitutes the equivalent coefficient corresponding to the operation and the running time into a predetermined equivalent running time calculating formula to calculate the equivalent running time. The type of the equivalent running time calculating formula is determined in the previous stage of the process of calculating the deterioration function in advance.

The deterioration function calculation unit 114 calculates the deterioration function indicating relationships of the equivalent running times and the deterioration rates based on the equivalent running times calculated by the first equivalent running time calculation unit 113 and the deterioration rates. To be specific, the deterioration function calculation unit 114 reads the deterioration rates associated with the running times used for calculating the equivalent running times from the storage unit 111 and generates a plurality of combinations of the equivalent running times and the deterioration rates. The deterioration function calculation unit 114 performs curve fitting based on the combinations to calculate the deterioration function.

The deterioration function evaluation unit 115 calculates dispersion of the deterioration function calculated by the deterioration function calculation unit 114 and the deterioration rates and determines that the deterioration function is appropriate when the dispersion is less than a predetermined threshold value. Note that, in the embodiment, a case in which the deterioration function evaluation unit 115 evaluates the deterioration function based on the dispersion of the deterioration rates has been described, but the deterioration function evaluation unit 115 is not limited thereto. In another embodiment, the deterioration function may be evaluated based on degrees of scattering of, for example, a standard deviation, a range, etc. instead of the dispersion.

The deterioration rate estimation device 120 estimates the deterioration rates of the secondary battery using the deterioration function calculated by the deterioration function calculation device 110. The deterioration rate estimation device 120 includes an input unit 121, a second equivalent coefficient calculation unit 122, a second equivalent running time calculation unit 123, and a deterioration rate estimation unit 124.

The input unit 121 receives inputs of load patterns and running times of the secondary battery that is an estimation target of the deterioration rates. The load patterns received by the input unit 121 as the inputs are defined by the values related to the operations used for calculating the equivalent coefficients.

The second equivalent coefficient calculation unit 122 calculates the equivalent coefficients from the load patterns received by the input unit 121 based on the equivalent coefficient calculating formula used for calculating the equivalent coefficients by the first equivalent coefficient calculation unit 112.

The second equivalent running time calculation unit 123 substitutes the equivalent coefficients calculated by the second equivalent coefficient calculation unit 122 and the running times received by the input unit 121 as the inputs into the equivalent running time calculating formula to calculate the equivalent running times.

The deterioration rate estimation unit 124 estimates the deterioration rates of the secondary battery that is the estimation target from the running times calculated by the second equivalent running time calculation unit 123 based on the deterioration function calculated by the deterioration function calculation device 110.

As described above, the deterioration function calculation device 110 and the deterioration rate estimation device 120 can use equivalent running times obtained by normalizing the running times of the operations due to different load patterns to reduce errors of estimation due to differences of the load patterns.

A method of calculating a deterioration function using the deterioration function calculation device 110 according to the first embodiment will be described.

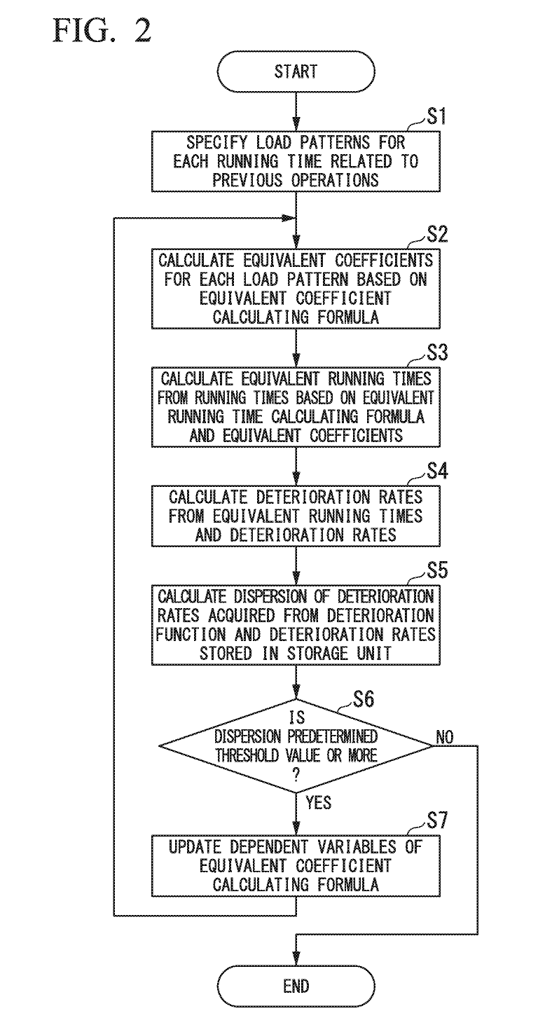

FIG. 2 is a flowchart showing the method of calculating the deterioration function according to the first embodiment.

Relationships of running times and deterioration rates related to previous operations of a secondary battery with the same performance as the secondary battery that is an estimation target of the deterioration rates are recorded in the storage unit 111 before the deterioration function is calculated. For example, experimental data of secondary batteries of the same type, actual operation data, etc. are recorded in the storage unit 111.

When data is recorded in the storage unit 111, the first equivalent coefficient calculation unit 112 specifies load patterns related to running times stored by the storage unit 111 for each running time (Step S1). To be specific, the equivalent coefficient calculation unit reads values related to the operations associated with the running times before the funning times and integrates the read values related to the operations to specify the load patterns.

The first equivalent coefficient calculation unit 112 substitutes the specified load patterns into the equivalent coefficient calculating formula and calculates the equivalent coefficients (Step S2). Subsequently, the first equivalent running time calculation unit 113 calculates the equivalent running times for the running times stored by the storage unit 111 based on the equivalent coefficients corresponding to the operations related to the running times and the equivalent running time calculating formula (Step S3).

Subsequently, the deterioration function calculation unit 114 performs curve fitting based on combinations of the equivalent running times calculated by the first equivalent running time calculation unit 113 and the deterioration rates associated with the running times used for calculating the equivalent running times and calculates the deterioration function (Step S4). The curve fitting can be performed through, for example, a polynomial approximation.

The deterioration function evaluation unit 115 calculates dispersion of the deterioration function calculated by the deterioration function calculation unit 114 and the degree of deterioration stored by the storage unit 111 (Step S5). To be specific, the dispersion of the degrees of deterioration stored by the storage unit 111 and the degrees of deterioration obtained by substituting the equivalent running times combined with the degrees of deterioration into the deterioration function is calculated. Note that the dispersion is an example of degrees of scattering. The deterioration function evaluation unit 115 determines whether the dispersion is a predetermined threshold value or more (Step S6).

The deterioration function evaluation unit 115 determines that the accuracy of the equivalent coefficient calculating formula and the deterioration function is not sufficient when the calculated dispersion is the predetermined threshold value or more (Step S6: YES). The first equivalent coefficient calculation unit 112 updates dependent variables of the equivalent coefficient calculating formula such that the dispersion calculated by the deterioration function evaluation unit 115 becomes smaller (Step S7). Then, the process returns to Step S2, and the equivalent coefficient is calculated using the updated equivalent coefficient calculating formula. In other words, the first equivalent coefficient calculation unit 112 generates the equivalent coefficients such that degrees of scattering between the deterioration rates stored by the storage unit 111 and deterioration rates acquired from the equivalent running times calculated based on the running times associated with the deterioration rates and the deterioration function become smaller. Thus, the accuracy of the deterioration function calculated by the deterioration function calculation unit 114 can be secured to a predetermined level or more.

On the other hand, the deterioration function evaluation unit 115 determines that the accuracy of the equivalent coefficient calculating formula and the deterioration function is sufficient when the calculated dispersion is less than the threshold value (Step S6: NO) and ends the process of calculating the deterioration function. Thus, the deterioration function calculation device 110 can accurately generate the deterioration function indicating relationships of the equivalent running times and the deterioration rates. Therefore, the deterioration function calculation device 110 determines the equivalent coefficient calculating formula which calculates the equivalent coefficients.

A method of estimating a deterioration rate using the deterioration rate estimation device 120 according to the first embodiment will be described.

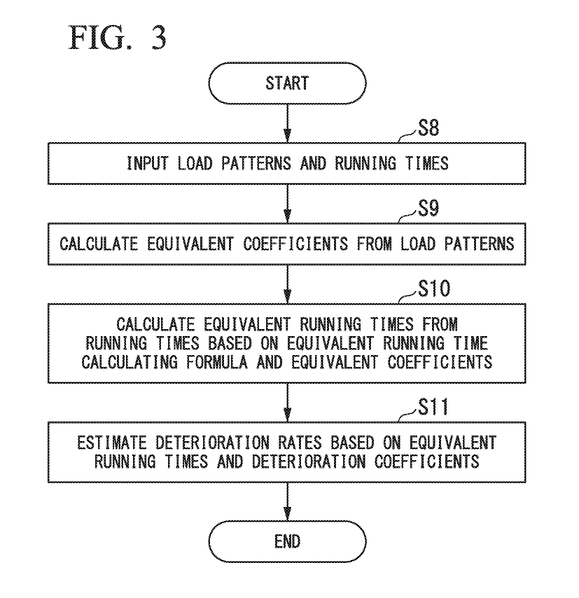

FIG. 3 is a flowchart showing the method of estimating the deterioration rate according to the first embodiment.

The deterioration rate estimation device 120 estimates the deterioration rates of the secondary battery when the deterioration function is calculated by the deterioration function calculation device 110.

The input unit 121 receives inputs of load patterns and running times of the secondary battery that is the estimation target of the deterioration rates from a manager of the secondary battery, etc. (Step S8). The second equivalent coefficient calculation unit 122 calculates the equivalent coefficients using the equivalent coefficient calculating formula used by the first equivalent coefficient calculation unit 112 based on the load patterns received by the input unit 121 as the inputs (Step S9). In other words, the second equivalent coefficient calculation unit 122 calculates the equivalent coefficient using the equivalent coefficient calculating formula determined to be sufficiently accurate by the deterioration function evaluation unit 115.

The second equivalent running time calculation unit 123 calculates the equivalent running times from the running times received by the input unit 121 as the inputs based on the equivalent coefficients calculated by the second equivalent coefficient calculation unit 122 and a predetermined equivalent running time calculating formula (Step S10). An equivalent running time calculating formula used by the second equivalent running time calculation unit 123 is the same as the equivalent running time calculating formula used by the first equivalent running time calculation unit 113.

The deterioration rate estimation unit 124 estimates the deterioration rates of the secondary battery that is the estimation target from the running times calculated by the second equivalent running time calculation unit 123 based on the deterioration function calculated by the deterioration function calculation device 110 and the equivalent running times calculated by the second equivalent running time calculation unit 123 (Step S11).

As described above, according to the present embodiment, the deterioration rate estimation system 100 calculates the deterioration function and estimates the deterioration rates using the equivalent running times obtained by normalizing the running times based on the load patterns related to the operations. Thus, the deterioration rate estimation system 100 can estimate the deterioration rate irrespective of the load patterns related to the operations. In other words, according to the deterioration rate estimation system 100 of the embodiment, even when the secondary battery is operated in an unknown load pattern, the deterioration rate of the secondary battery can be accurately estimated.

A calculation of the deterioration function according to the first embodiment

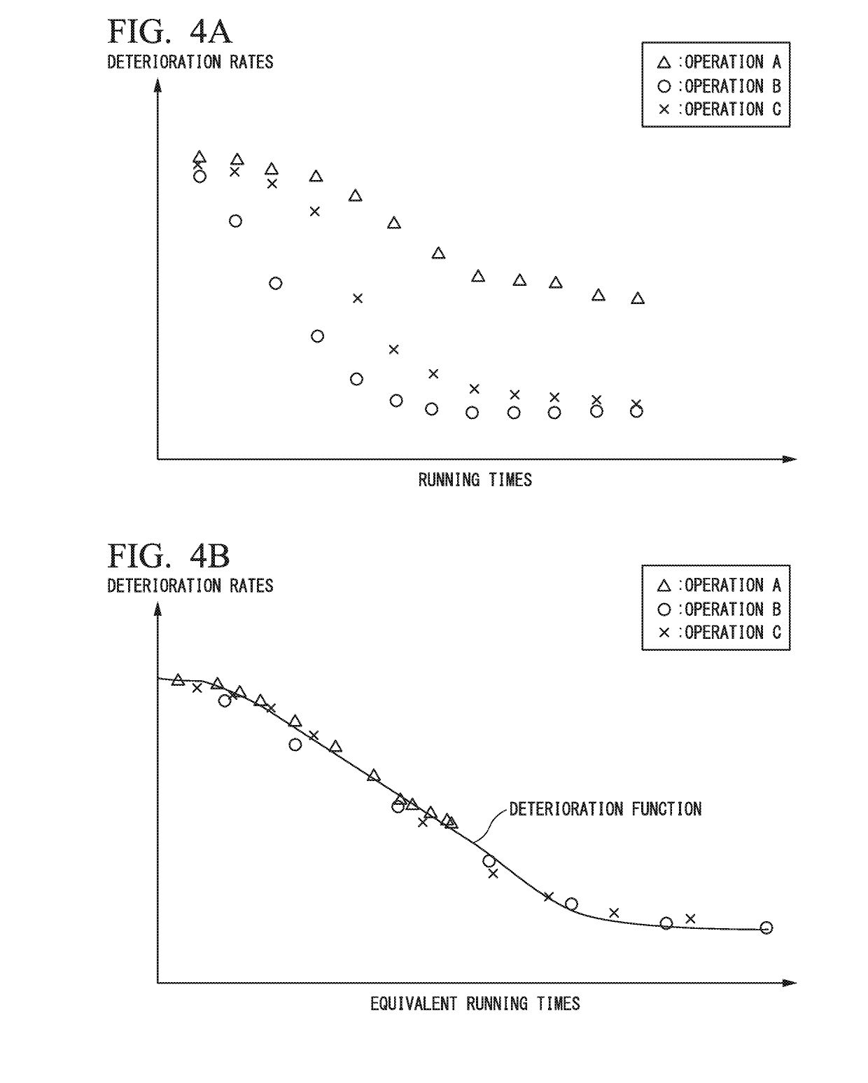

will be described using specific examples. FIGS. 4A and 4B are views showing examples of a method of calculating a deterioration function according to the first embodiment.

As shown in FIG. 4A, running times and deterioration rates of the secondary battery in previous operations of the secondary battery are associated for each operation in the storage unit 111. The first equivalent running time calculation unit 113 calculates the equivalent running times from the running times shown in FIG. 4A. Thus, relationships of the equivalent running times and the deterioration rates can he acquired as shown in FIG. 4B. Also, the deterioration function calculation unit 114 can perform curve fitting based on the relationships of the equivalent running times and the deterioration rates shown in FIG. 4B to acquire the deterioration function (deterioration curves) shown in FIG. 4B.

### Second Embodiment

When a secondary battery is operated in an actual device, types of values related to operations which can be acquired and sampling periods are likely to be limited compared with when a measurement test is performed in a laboratory. For example, while the sampling periods can be used in units of seconds in the measurement test, the sampling periods may be capable of being used only in units of minutes in the actual device. While a current, a voltage, a temperature, and a charging rate can be acquired as the values related to the operations in the measurement test, only a temperature and a charging rate may be capable of being acquired in the actual device. This is to decrease the amount of data by lengthening the sampling periods or reducing the types of the values related to the operations because the secondary battery is generally operated for a long time, for example, five years or ten years.

A deterioration rate estimation system 200 of a second embodiment calculates an appropriate deterioration function and more accurately estimates the deterioration rates even under limited conditions.

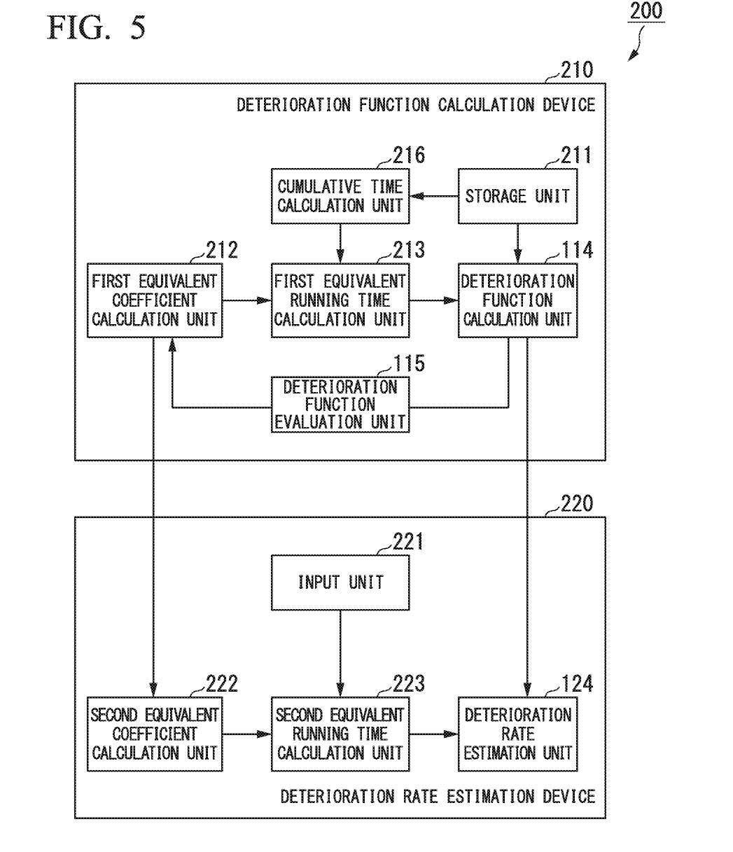

FIG. 5 is a schematic block diagram showing a constitution of the deterioration rate estimation system 200 according to the second embodiment.

In the deterioration rate estimation system 200 of the second embodiment, a deterioration function calculation device 210 includes a cumulative time calculation unit 216 in addition to the constitution of the first embodiment. The deterioration rate estimation system 200 of the second embodiment is different from that of the first embodiment in view of information received by an input unit 221 as inputs and processes of a first equivalent coefficient calculation unit 212, a first equivalent running time calculation unit 213, a second equivalent coefficient calculation unit 222, and a second equivalent running time calculation unit 223.

The cumulative time calculation unit 216 calculates the cumulative time of operations (a partial running time) for each operation condition during running times after operating starts, with respect to the running times that stored by a storage unit 211. For example, the cumulative time calculation unit 216 calculates the cumulative time that the charging rate of the secondary battery is less than 20%, the cumulative time that the charging rate of the secondary battery is 20% or more and less than 40%, the cumulative that the charging rate of the secondary battery is 40% or more and less than 60%, the cumulative time that the charging rate of the secondary battery is 60% or more and less than 80%, and a cumulative time at which the charging rate of the secondary battery is 80% or more during the running time after the operating starts. Usage ranges of the charging rates of the secondary battery are examples of operation conditions. The cumulative time calculation unit 216 calculates the cumulative times similarly under other operation conditions such as ranges of rates of change of the charging rates and ranges of temperature.

The first equivalent coefficient calculation unit 212 calculates the equivalent coefficients for each operation condition. The first equivalent coefficient calculation unit 212 may calculate the equivalent coefficients of the operation conditions based on a predetermined numerical formula and may calculate the equivalent coefficients of the operation conditions based on a predetermined probability regardless of the numerical formula.

The first equivalent running time calculation unit 213 calculates sums of values obtained by multiplying the cumulative times calculated by the cumulative time calculation unit 216 by the equivalent coefficients calculated by the first equivalent coefficient calculation unit 212 as the equivalent running times for each running time.

The input unit 221 receives inputs of the cumulative times for each operation condition until the present time after the operation of the secondary battery that is the estimation target of the deterioration rates starts.

The second equivalent, coefficient calculation unit 222 calculates the same equivalent coefficients as the first equivalent coefficient calculation unit 212 for each operation condition.

The second equivalent running time calculation unit 223 calculates sums of values obtained by multiplying the cumulative times calculated by a second cumulative time calculation unit 216 by the equivalent coefficients calculated by the second equivalent coefficient calculation unit 222 as the equivalent miming times for each running time.

A method of calculating a deterioration function using the deterioration function calculation device 210 according to the second embodiment will be described.

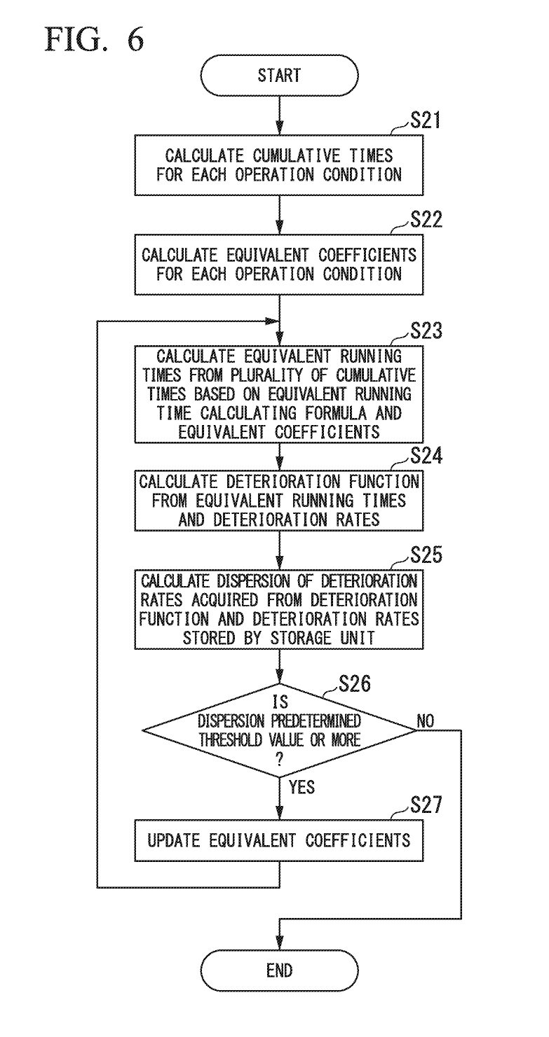

FIG. 6 is a flowchart showing the method of calculating the deterioration function according to the second embodiment.

The cumulative time calculation unit 216 calculates the cumulative times of the operations for each operation condition during an running time after operating starts with respect to the running times stored by the storage unit 211 (Step S21). The first equivalent coefficient calculation unit 212 calculates the equivalent coefficients for each operation condition (Step S22).

Subsequently, the first equivalent running time calculation unit 213 calculates sums of values obtained by multiplying the cumulative times calculated by the cumulative time calculation unit 216 by the equivalent coefficients calculated by the first equivalent coefficient calculation unit 212 as the equivalent running times (Step S23). Subsequently, the deterioration function calculation unit 114 performs curve fitting based on combinations of the equivalent running times calculated by the first equivalent running time calculation unit 213 and the deterioration rates associated with the running times used for calculating the equivalent running times and calculates the deterioration function (Step S24).

The deterioration function evaluation unit 115 calculates dispersion of the deterioration function calculated by the deterioration function calculation unit 114 and the degrees of deterioration stored by the storage unit 211 (Step S25). The deterioration function evaluation unit 115 determines whether the dispersion is a predetermined threshold value or more (Step S26).

The deterioration function evaluation unit 115 determines that the accuracy of the equivalent coefficients and the deterioration function is not sufficient when the calculated dispersion is the predetermined threshold value or more (Step S26: YES). The first equivalent coefficient calculation unit 212 updates the equivalent coefficients such that the dispersion calculated by the deterioration function evaluation unit 115 become smaller (Step S27), and the process returns to Step S23.

On the other hand, the deterioration function evaluation unit 115 determines that the accuracy of the equivalent coefficient calculating formula and the deterioration function is sufficient when the calculated dispersion is less than the predetermined threshold value (Step S26: NO), and the process of calculating the deterioration function ends. Thus, the deterioration function calculation device 210 can accurately generate the deterioration function indicating relationships of the equivalent running times and the deterioration rates. Therefore, the deterioration function calculation device 210 determines the equivalent coefficients.

A method of estimating a deterioration rate using the deterioration rate estimation device 220 according to the second embodiment will be described.

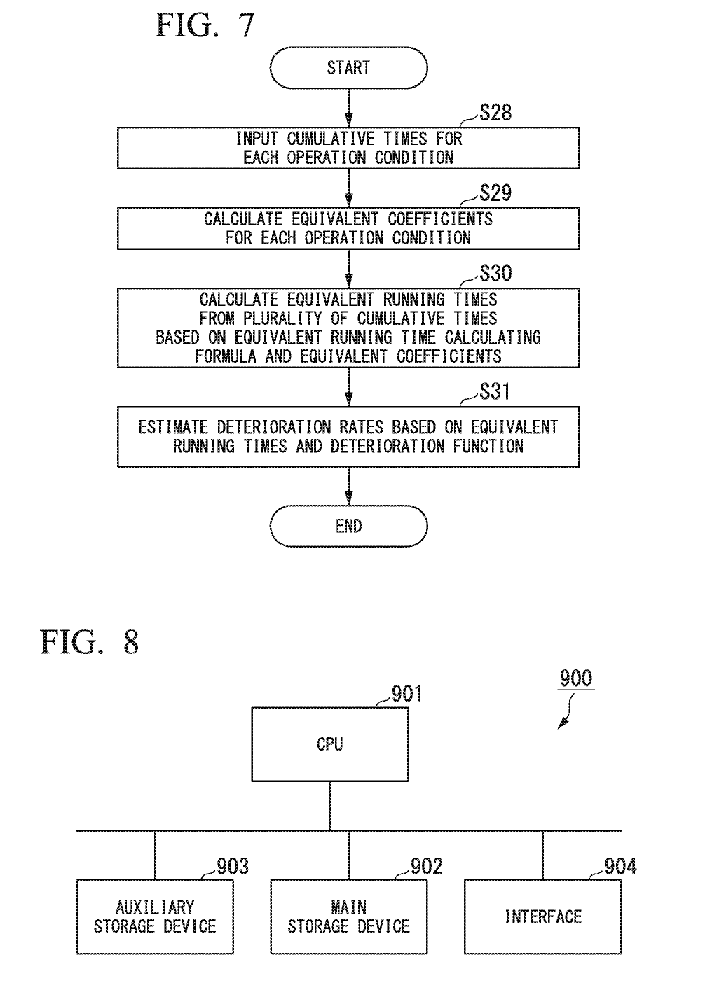

FIG. 7 is a flowchart showing the method of estimating the deterioration rate according to the second embodiment.

The deterioration rate estimation device 220 estimates the deterioration rates of the secondary battery when the deterioration function is calculated by the deterioration function calculation device 210.

The input unit 221 receives inputs of cumulative times for each operation condition of a secondary battery that is the estimation target of the deterioration rates from a user such as a manager of the secondary battery (Step S28). Subsequently, the second equivalent coefficient calculation unit 222 calculates the equivalent coefficients which are finally calculated by the first equivalent coefficient calculation unit 212 as the equivalent coefficients used for estimating the deterioration rates (Step S29).

The second equivalent running time calculation unit 223 calculates the equivalent running times from the cumulative times for each operation condition received by the input unit 221 as the inputs based on the equivalent coefficients calculated by the second equivalent coefficient calculation unit 222 and a predetermined equivalent running time calculating formula (Step S30). An equivalent running time calculating formula used by the second equivalent running time calculation unit 223 is the same as the equivalent running time calculating formula used by the first equivalent running time calculation unit 213.

The deterioration rate estimation unit 124 estimates the deterioration rates of the secondary battery that is the estimation target from the running times calculated by the second equivalent running time calculation unit 223 based on the deterioration function calculated by the deterioration function calculation device 210 and the equivalent running times calculated by the second equivalent running time calculation unit 223 (Step S31).

As described above, according to the embodiment, the deterioration rate estimation system 200 calculates the cumulative times for a plurality of operation conditions from limited data and calculates equivalent running times from the cumulative times. Thus, the deterioration rate estimation system 200 can appropriately estimate the deterioration rates even When the values related to the operations which can be acquired are limited. Also, the values related to the operations of the secondary battery can be integrated as the cumulative times for the plurality of operation conditions to reduce the amount of data compared with when the values related to the operations such as currents, voltages, charging rates, and temperatures of the times are accumulated even when data is accumulated for a long time such as five years or ten years.

Although embodiments have been described in detail above with reference to the drawings, the specific constitutions are not limited to the above-mentioned constitutions and various changes in design, etc. are also possible.

FIG. 8 is a schematic block diagram showing a constitution of a computer 900 according to at least one embodiment.

The computer 900 includes a CPU 901, a main storage device 902, an auxiliary storage device 903, and an interface 904.

The above-mentioned deterioration rate estimation systems 100 and 200 are installed in the computer 900. Also, the above-mentioned operations of the processing units are stored in the auxiliary storage device 903 in the form of a program. The CPU 901 reads the program from the auxiliary storage device 903, develops the program on the main storage device 902, and executes the above-mentioned processes according to the program. In addition, the CPU 901 secures storage regions corresponding to the above-mentioned storage units 111 and 211 in the main storage device 902 according to the program.

Note that the auxiliary storage device 903 is an example of a non-transitory medium in the at least one embodiment. Other examples of the non-transitory media may include a magnetic disk, a magneto-optical disc, a CD-ROM, a DVD-ROM, a semiconductor memory, etc. connected through the interface 904. Also, when the program is delivered to the computer 900 through communication lines, the computer 900 which receives the delivered program may develop the program on the main storage device 902 and execute the above-mentioned processes.

Also, the program may be for the purpose of implementing some of the above-mentioned functions. The program may be so-called differential tiles (differential program) in which the above-mentioned functions are realized in combination with other programs which have already been stored in the auxiliary storage device 903,

Also, the deterioration function calculation device and the deterioration rate estimation device may be installed in separate computers 900.

### INDUSTRIAL APPLICABILITY

The deterioration function calculation device can calculate a deterioration function for the purpose of accurately estimating the deterioration rates even when the secondary battery is operated in an unknown operation aspect. The deterioration rate estimation device can accurately estimate the deterioration rates even when the secondary battery is operated in an unknown operation aspect.

### REFERENCE SIGNS LIST

100: deterioration rate estimation system

110: deterioration function calculation device

111: storage unit

112: first equivalent coefficient calculation unit

113: first equivalent running time calculation unit

114: deterioration function calculation unit

115: deterioration function evaluation unit

120: deterioration rate estimation device

121: input unit

122: second equivalent coefficient calculation unit

123: second equivalent running time calculation unit

124: deterioration rate estimation unit

200: deterioration rate estimation system

210: deterioration function calculation device

211: storage unit

212: first equivalent function calculation unit

213: first equivalent running time calculation unit

216: cumulative time calculation unit

220: deterioration rate estimation device

221: input unit

222: second equivalent coefficient calculation unit

223: second equivalent running time calculation unit

1. A deterioration function calculation device comprising:
a storage unit configured to associate and store running times of a secondary battery in previous operations of the secondary battery with deterioration rates of the secondary battery in the running times for every operation;
an equivalent coefficient calculation unit configured to calculate equivalent coefficients used to normalize the running times based on values related to the previous operations in the secondary battery for every operation;
an equivalent running time calculation unit configured to calculate equivalent running times that are the normalized running times based on the running times and the equivalent coefficients related to the operations relevant to the running times with respect to the running times associated and stored with the operations and the deterioration rates by the storage unit; and
a deterioration function calculation unit configured to calculate a deterioration function indicating relationships of the equivalent running times and the deterioration rates based on the equivalent running times and the deterioration rates associated with the running times used for calculating the equivalent running times and stored by the storage unit.

2. The deterioration function calculation device according to claim 1, wherein the equivalent coefficient calculation unit generates the equivalent coefficients such that degrees of scattering between the deterioration rates stored by the storage unit, and the equivalent running times calculated based on the running times associated with the deterioration rates and the deterioration rates acquired from the deterioration function become smaller.

3. The deterioration function calculation device according to claim 1, wherein the equivalent running time calculation unit divides the running times into partial running times for every operation state, multiplies the partial running times by the equivalent coefficients according to operation states, calculates a sum thereof, and calculates the equivalent running times.

4. A deterioration rate estimation device comprising:
an input unit configured to receive inputs of running times of a secondary battery and values related to operations of the secondary battery;
an equivalent coefficient calculation unit configured to calculate equivalent coefficients used to normalize the running times based on the values related to the operations received as the inputs;
an equivalent running time calculation unit configured to calculate equivalent running times that are the normalized running times based on the running times received as the inputs and the equivalent coefficients; and
a deterioration rate estimation unit configured to estimate the deterioration rates of the secondary battery based on a deterioration function which is calculated based on equivalent running times in previous operations of the secondary battery and deterioration rates of the secondary battery in the operations and indicates relationships of the equivalent running times and the deterioration rates of the secondary battery, and the calculated equivalent running times.

5. The deterioration rate estimation device according to claim 4, wherein the deterioration rate estimation unit estimates the deterioration rates of the secondary battery based on a deterioration function calculated by the deterioration function calculation unit of the deterioration function calculation device according to claim 1 and the calculated equivalent running times.

6. A deterioration function calculating method of calculating a deterioration function used for estimating deterioration rates of a secondary battery, the deterioration function calculating method comprising:
a step of calculating, by a deterioration function calculation device, equivalent coefficients used to normalize running times of the secondary battery based on values related to previous operations of the secondary battery for every operation;
a step of calculating, by the deterioration function calculation device, equivalent running times that are the normalized running times bases on the running times and the equivalent coefficients related to the operations relevant to the running times with respect to the running times associated and stored with the operations and the deterioration rates in a storage unit configured to associate and store the running times of the secondary battery in the previous operations of the secondary battery with the deterioration rates of the secondary battery in the running times for every operation; and
a step of calculating, by the deterioration function calculation device, a deterioration function indicating relationship between the equivalent running times and the deterioration rates based on the equivalent running times and the deterioration rates associated with the running times used for calculating the equivalent running times and stored by the storage unit.

7. A deterioration rate estimating method of estimating deterioration rates of a secondary battery, the deterioration rate estimating method comprising:
a step of receiving, by a deterioration rate estimation device, inputs of running times of the secondary battery and values related to operations of the secondary battery;
a step of calculating, by the deterioration rate estimation device, equivalent coefficients used to normalize the running times based on the values related to the operations received as the inputs;
a step of calculating, by the deterioration rate estimation device, equivalent running times that are the normalized running times based on the running times received as the inputs and the equivalent coefficients; and
a step of estimating, by the deterioration rate estimation device, the deterioration rates of the secondary battery based on a deterioration function which is calculated based on equivalent running times in previous operations of the secondary battery and deterioration rates of the secondary battery in the operations and indicates relationships of the equivalent running times and the deterioration rates of the secondary battery, and the calculated equivalent running times.

8. A non-transitory medium storing a program causing a computer to function as:
a storage unit configured to associate and store running times of a secondary battery in previous operations of the secondary battery with deterioration rates of the secondary battery in the running times for every operation;
an equivalent coefficient calculation unit configured to calculate equivalent coefficients used to normalize the running times based on values related to the previous operations in the secondary battery for every operation;
an equivalent running time calculation unit configured to calculate equivalent running times that are the normalized running times based on the running times and the equivalent coefficients related to the operations relevant to the running times with respect to the running times associated with the operations and the deterioration rates and stored by the storage unit; and
a deterioration function calculation unit configured to calculate a deterioration function indicating relationships of the equivalent running times and the deterioration rates based on the equivalent running times and the deterioration rates associated with the running times used for calculating the equivalent running times and stored by the storage unit.

9. A non-transitory medium storing a program causing a computer to function as:
an input unit configured to receive inputs of running times of a secondary battery and values related to operations of the secondary battery;
an equivalent coefficient calculation unit configured to calculate equivalent coefficients used to normalize the running times based on the values related to the operations received as the inputs;
an equivalent running time calculation unit configured to calculate equivalent running times that are the normalized running times based on the running times received as the inputs and the equivalent coefficients; and
a deterioration rate estimation unit configured to estimate the deterioration rates of the secondary battery based on a deterioration function which is calculated based on equivalent running times in previous operations of the secondary battery and deterioration rates of the secondary battery in the operations and indicates relationships of the equivalent running times and the deterioration rates of the secondary battery, and the calculated equivalent running times.

10. A deterioration rate estimating system comprising:
a storage unit configured to associate and store running times of a secondary battery in previous operations of the secondary battery with deterioration rates of the secondary battery in the running times for every operation;
a first equivalent coefficient calculation unit configured to calculate equivalent coefficients used to normalize the running times based on values related to the previous operations in the secondary battery for every operation;
a first equivalent running time calculation unit configured to calculate equivalent running times that are the normalized running times based on the running times and the equivalent coefficients calculated by the first equivalent coefficient calculation unit with respect to the running times associated and stored with the operations and the deterioration rates by the storage unit;
a deterioration function calculation unit configured to calculate a deterioration function indicating relationships of the equivalent running times and the deterioration rates based on the equivalent running times calculated by the first equivalent running time calculation unit and the deterioration rates associated and stored with the running times used for calculating the equivalent running times by the storage unit;
an input unit configured to receive inputs of running times of a secondary battery and values related to operations of the secondary battery;
a second equivalent coefficient calculation unit configured to calculate equivalent coefficients used to normalize the running times based on the values related to the operations received as the inputs;
a second equivalent running time calculation unit configured to calculate equivalent running times that are the normalized running times based on the running times received as the inputs and the equivalent coefficients calculated by the second equivalent coefficient calculation unit; and
a deterioration rate estimation unit configured to estimate the deterioration rates of the secondary battery based on the deterioration function calculated by the deterioration function calculation unit and the equivalent running times calculated by the second equivalent running time calculation unit.
